(19) United States
(12) Patent Application Publication
(10) Pub. No.: US 2023/0318212 A1
(43) Pub. Date: Oct. 5, 2023

(54) COMPOSITE STRUCTURE OF CERAMIC SUBSTRATE

(71) Applicant: PRINCO CORP., Hsinchu City (TW)

(72) Inventor: Pei-Liang CHIU, Hsinchu City (TW)

(21) Appl. No.: 17/883,847

(22) Filed: Aug. 9, 2022

(30) Foreign Application Priority Data
Mar. 14, 2022 (TW) 111109273

(51) Int. Cl. H01R 12/73; C30B 29/20; C30B 29/38; C30B 29/66

(52) U.S. Cl. CPC H01R 12/732; C30B 29/20; C30B 29/38; C30B 29/66

(57) ABSTRACT

A composite structure of a ceramic substrate, including a first ceramic substrate formed by crystal growth, which has a first surface and a second surface opposite to each other, and has only vertical via holes filled with conductive material, so that the first surface and the second surface of the first ceramic substrate are electrically connected; and a thin film substrate disposed on the second surface of the first ceramic substrate, and one of the surfaces is electrically connected to the second surface of the first ceramic substrate, and an electrical connection point is provided on the other surface of the thin film substrate to electrically connect an external element or another circuit board.

### FIELD OF INVENTION

The present invention relates to a field of a structure of a ceramic substrate, and more particularly to a composite structure of a ceramic substrate suitable for various applications.

### BACKGROUND

Conventional ceramic substrates are usually formed by a co-sintered method and can be used in applications such as a body of circuit boards. However, conventional ceramic substrates are often formed with holes and stress after sintering, and there are inevitably problems such as formation of undesired holes and deformation of the substrates.

In addition, in response to the substantial increases in demands of refined circuit boards in the future, fabrication of refined circuits in the ceramic substrates is limited by its co-sintered method, which will face problems such as a thickness cannot be reduced and the greatly increased costs.

Furthermore, for future communication applications using 5G millimeter-wave high-frequency signals, although a dielectric constant of the material used in the ceramic substrate is lower than that of the FR4 material used in conventional printed circuit boards, however a decay rate of the high-frequency signals is still too high, which is not conducive to use the conventional ceramic substrates formed by the co-sintered method in the application of communication fields.

### SUMMARY

In view of this, the present invention provides a composite structure of a ceramic substrate to solve the problems encountered by the conventional probe card device described above.

According to an embodiment, a composite structure of a ceramic substrate is provided, comprising a first ceramic substrate and a thin film substrate. The first ceramic substrate is formed by crystal growth and has a first surface and a second surface opposite to each other. The first ceramic substrate comprises a plurality of vertical via holes filled with a conductive material so that the first surface and the second surface of the first ceramic substrate are electrically connected. The thin film substrate is disposed on the second surface of the first ceramic substrate, having one surface electrically connected to the second surface of the first ceramic substrate and a plurality of electrical connection points disposed on the other surface of the thin film substrate to electrically connect an external element or a circuit board.

In one embodiment, the first ceramic substrate comprises aluminum oxide or aluminum nitride.

In one embodiment, the composite structure of the ceramic substrate further comprises a heat insulating layer disposed between the second surface of the first ceramic substrate and the thin film substrate to isolate heats from the external element or the circuit board connected to second the surface of the first ceramic substrate from the ceramic substrate. The heat insulating layer does not affect the electrical connection between the second surface of the ceramic substrate and the thin film substrate.

In one embodiment, the composite structure of the ceramic substrate further comprises a second ceramic substrate and a plurality of electrical connection points. The second ceramic substrate is disposed on a surface of the thin film substrate away from the first ceramic substrate. The second ceramic substrate comprises a third surface and a fourth surface opposite to each other, and the second ceramic substrate comprises a plurality of vertical via holes filled with a conductive material so that the third surface and the fourth surface of the first ceramic substrate are electrically connected, and the third surface of the second ceramic substrate is electrically connection to the other surface of the thin film substrate. The plurality of electrical connection points are disposed on the fourth surface of the second ceramic substrate to electrically connect an external element or a circuit board.

In one embodiment, the second ceramic substrate comprises aluminum oxide or aluminum nitride.

### BRIEF DESCRIPTION OF DRAWINGS

To detailly explain the technical schemes of the embodiments or existing techniques, drawings that are used to illustrate the embodiments or existing techniques are provided. The illustrated embodiments are just a part of those of the present disclosure. It is easy for any person having ordinary skill in the art to obtain other drawings without labor for inventiveness.

FIG. 1 is a schematic cross-section showing a ceramic substrate according to a first embodiment of the present invention.

FIG. 2 is a schematic cross-section of a composite structure of a ceramic substrate according to a second embodiment of the present invention.

FIG. 3 is a schematic cross-section showing a thin film substrate according to a third embodiment of the present invention.

FIG. 4 is a schematic cross-section showing a composite structure of a ceramic substrate according to a fourth embodiment of the present invention.

FIG. 5 is a schematic cross-section showing a composite structure of a ceramic substrate according to a fifth embodiment of the present invention.

### DETAILED DESCRIPTION

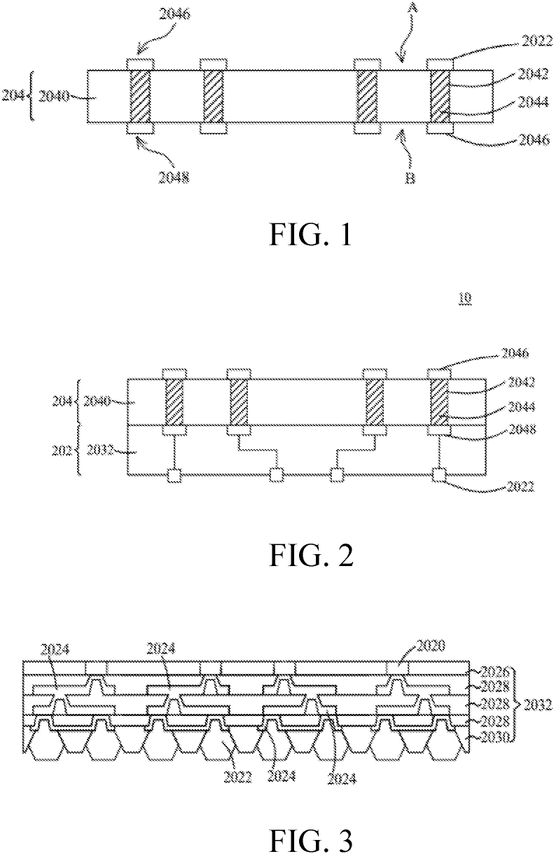

Technical solutions in the embodiments of the present invention will be clearly described below with reference to FIGS. 1-5 of the accompanying drawings in the embodiments of the present invention. Obviously, the described embodiments are only some, but not all, embodiments of the present invention. Based on the embodiments of the present invention, all other embodiments obtained by those skilled in the art without creative work fall within the protection scope of the present invention.

Please refer to FIG. 1, a schematic cross-section of a ceramic substrate 204 according to the first embodiment of the present invention is shown. Herein, a body 2040 of the ceramic substrate 204 comprises materials such as aluminum oxide (Al₂O₃) or aluminum nitride (AlN) formed by crystal growth. The body 2040 of the ceramic substrate 204 has a first surface A and a second surface B opposite to each other, and a plurality of vertical via holes 2042 are formed in the body 2040 to penetrate the first surface A and the second surface B, and the vertical via holes 2042 are formed in the body 2040. The vertical via holes 2042 can be formed by a method such as laser drilling or etching, and a conductive material 2044 such as copper can be filled in the vertical via holes 2042. A plurality of electrical connection points 2046 are also disposed on the first surface A, which are respectively located on the conductive material 2044 and the vertical via holes 2042 to electrically connect external components or circuits. In addition, a plurality of electrical connection points 2048 are disposed on the second surface B of the ceramic substrate structure 204 and are respectively located under each conductive material 2044 and the vertical via holes 2042 to electrically connect to another external element or another circuit board. The conductive material 2044 in the vertical via holes 2042 respectively contact the electrical connection points 2046 formed on the first surface A of the ceramic substrate structure 204 and the electrical connection points 2048 formed on the second surface B of the ceramic substrate structure 204.

Please refer to FIG. 2, a schematic cross-section of a composite structure 10 of a ceramic substrate according to a second embodiment of the present invention is shown. Herein, the composite structure 10 of the ceramic substrate comprises the ceramic substrate 204 shown in FIG. 1 and a thin film substrate 202. The thin film substrate 202 is disposed on the second surface B of the ceramic substrate 204 (see FIG. 1), and a surface of the thin film substrate 202 away from the ceramic substrate 204 is provided with a plurality of electrical connection points 2022 to electrically connect other external components or another circuit board (not shown). The electrical connection points 2022 are electrically connected to the second surface B (see FIG. 1) of the ceramic substrate 204.

Please refer to FIG. 3, a schematic cross-section of a thin film substrate 202 according to a third embodiment of the present invention is shown. Herein, the thin film body 2032 of the thin film substrate 202 comprises a plurality of thin film connection points 2020, at least one internal metal layer 2024 and the electrical connection points 2022. The thin film body 2032 further comprises a first surface dielectric layer 2026, at least one internal dielectric layer 2028, and a second surface dielectric layer 2030. In this embodiment, the thin film substrate 202 comprises three internal metal layers 2024 and three internal dielectric layers 2028, but the invention is not limited thereto. The thin film connection points 2020 are electrically connected to the electrical connection points 2048 on the second surface of the ceramic substrate 204 and are electrically connected to the electrical connection point 2046 on the first surface A (see FIG. 1) by the electrical connection points 2048 on the second surface B (see FIG. 1).

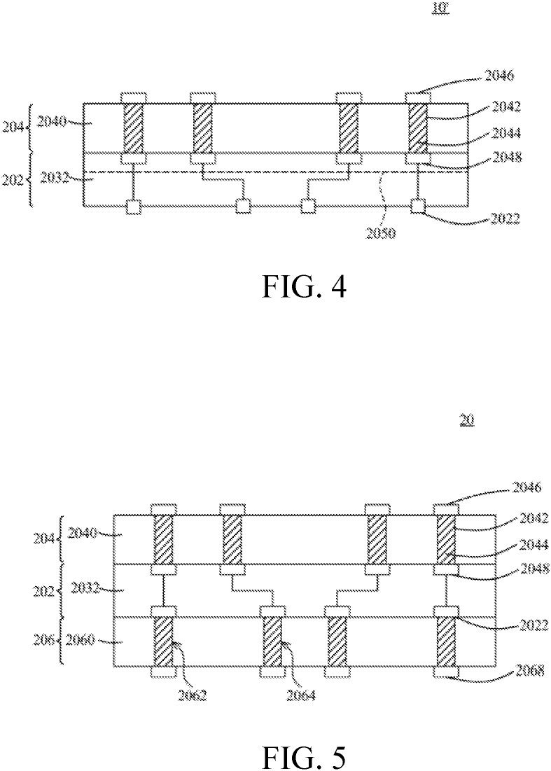

Please refer to FIG. 4, a schematic cross-section of a composite structure 10′ of a ceramic substrate according to a fourth embodiment of the present invention is shown. Herein, the composite structure 10′ of the ceramic substrate is similar with the composite structure 10 of the ceramic substrate, and the difference therebetween is that a thermal insulation layer 2050 (indicated by dashed lines) is added between the second surface B of the ceramic substrate 204 and the film substrate 202 in the composite structure of the ceramic substrate 10′. The thermal insulation layer 2050 can insulate heat from the external components or the external circuits received by the first surface A (see FIG. 1) of the ceramic substrate 204, and the thermal insulation layer 2050 does not affect electrical connections between the second surface B of the ceramic substrate 204 and the thin film substrate 206.

Please refer to FIG. 5, a schematic cross-section of a composite structure 20 of a ceramic substrate according to a fifth embodiment of the present invention is shown. Here, the ceramic substrate composite structure 20 is similar with the composite structure 10 of the ceramic substrate, except that another ceramic substrate 206 is provided on the surface of the film substrate 202 without formation of the ceramic substrate 204. A configuration of the ceramic substrate 206 is similar with that of the ceramic substrate 204, and a body 2060 of the ceramic substrate 206 comprises material such as aluminum oxide (Al₂O₃) or aluminum nitride (AlN) formed by crystal growth. A plurality of vertical via holes 2062 are formed in the body 2060 of the ceramic substrate 206 to penetrate two opposite surfaces thereof. The vertical via holes 2062 can be formed by a method such as laser drilling or etching, and the vertical via holes 2062 can be filled with a conductive material 2064 such as copper. A plurality of electrical connection points 2068 are also disposed on a surface of the ceramic substrate 206 that is not in contact with the thin film substrate 202 to electrically connect external components or circuits (not shown). Through this arrangement, the two opposite surfaces of the ceramic substrate 206 are electrically connected, and the surface of the ceramic substrate 206 adjacent to the thin film substrate 202 is electrically connected to the thin film substrate 202.

In the composite structures of the ceramic substrate of the present invention shown in FIGS. 2, 4, 5, etc., since the ceramic substrate 204 comprises a body formed by crystal growth, the ceramic substrate 204 has the advantages of zero holes, zero residual stress, and excellent surface flatness that is close to a flat surface when compared with the ceramic substrate using the co-sintered ceramic material as the body, so there will be no problems such as formation of undesired holes and deformation of the substrate In addition, in each composite structure of the ceramic substrate of the present invention, conductive lines of the present invention are embedded in the thin film substrate 202, and an organic dielectric polyimide (PI) material commonly used in the thin film substrate 202 has a dielectric constant of about 3, which is also much lower than the dielectric constant of the traditional co-sintered alumina ceramic substrate having a dielectric constant of about of 9.4 or the dielectric constant of other ceramic materials. Obviously, a device prepared by using a composite structure of a ceramic substrate of the present invention has the advantages of less high frequency signal attenuation compared to a device prepared by using the co-sintered ceramic material, which is in line with the application trend of future high-frequency semiconductor development. In addition, the thin film substrate of the present invention is also easy to form a precise and ultra-thin circuit board, which is the mainstream of the existing high-end package to connect the high-end chip circuit board. Furthermore, the ceramic substrates of each composite structure of the ceramic substrate of the present invention have good heat dissipation and are also suitable for uses as a packaging substrate. Electronic components such as light-emitting diodes can be packaged thereon, robustness and a high thermal conductivity to a heating element of the ceramic substrates can be retained, and solutions for component packaging can be provided.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A composite structure of a ceramic substrate, comprising:
a first ceramic substrate formed by crystal growth, having a first surface and a second surface opposite to each other, wherein the first ceramic substrate comprises a plurality of vertical via holes filled with a conductive material so that the first surface and the second surface of the first ceramic substrate are electrically connected; and
a thin film substrate disposed on the second surface of the first ceramic substrate, having one surface electrically connected to the second surface of the first ceramic substrate and a plurality of electrical connection points disposed on the other surface of the thin film substrate to electrically connect an external element or a circuit board.

2. The composite structure of the ceramic substrate of claim 1, wherein the first ceramic substrate comprises aluminum oxide or aluminum nitride.

3. The composite structure of the ceramic substrate of claim 1, further comprising a heat insulating layer disposed between the second surface of the first ceramic substrate and the thin film substrate to isolate heats from the external element or the circuit board connected to second the surface of the first ceramic substrate from the ceramic substrate, wherein the heat insulating layer does not affect the electrical connection between the second surface of the ceramic substrate and the thin film substrate.

4. The composite structure of the ceramic substrate of claim 1, further comprising:
a second ceramic substrate disposed on a surface of the thin film substrate away from the first ceramic substrate, wherein the second ceramic substrate comprises a third surface and a fourth surface opposite to each other, and the second ceramic substrate comprises a plurality of vertical via holes filled with a conductive material so that the third surface and the fourth surface of the first ceramic substrate are electrically connected, and the third surface of the second ceramic substrate is electrically connection to the other surface of the thin film substrate; and
a plurality of electrical connection points disposed on the fourth surface of the second ceramic substrate to electrically connect an external element or a circuit board.

5. The composite structure of the ceramic substrate of claim 4, wherein the second ceramic substrate comprises aluminum oxide or aluminum nitride.
